(19) United States
(12) Patent Application Publication
(10) Pub. No.: US 2016/0276510 A1
(43) Pub. Date: Sep. 22, 2016

(54) PARTLY-TRANSPARENT THIN-FILM SOLAR MODULE

(71) Applicants: CHINA TRIUMPH INTERNATIONAL ENGINEERING CO., LTD., Shanghai (CN); CTF SOLAR GMBH, Dresden (DE)

(72) Inventors: Hilmar RICHTER, Dresden (DE); Tobias KIESEWETTER, Dresden (DE); Shou PENG, Shanghai (CN)

(73) Assignees: China Triumph International Engineering Co., Ltd., Shanghai (CN); CTF Solar GmbH, Dresden (DE)

(21) Appl. No.: 14/915,104

(22) PCT Filed: Aug. 27, 2014
(86) PCT No.: PCT/EP2014/068192

§ 371 Date: Jun. 3, 2016

(30) Foreign Application Priority Data
Aug. 30, 2013 (CN) 201310613095.X

(51) Int. Cl. H01L 31/0463; H01L 31/05; H01L 31/0224; H01L 31/048

(52) U.S. Cl. CPC H01L 31/0463; H01L 31/0481; H01L 31/0516; H01L 31/022441

(57) ABSTRACT

The present invention concerns a method for the manufacture of a partially transparent thin-layer solar module in which the opaque layers (primarily the semiconductor layer and the back contact layer) comprise defined surface regions which lack the material of these layers. These surface regions which are free of material may be produced by not coating them during manufacture or by retroactively removing them from the surface regions.

The invention relates to thin-layer solar modules wherein, by selectively removing specific portions of the opaque or only slightly transparent photovoltaically active surface, a desired partial transparency to incident light is obtained.

The term “transparency” as used herein should be understood to mean the ability to transmit light in the visible spectral region (380 nm to 780 nm) compared with the entire surface under consideration. Explicitly, it means that the surface under consideration (for example a solar module) may have regions which are highly opaque or completely opaque to light and also regions which are highly translucent. The term “partial transparency” as used in this context means that the surface under consideration is transparent to a portion of the incident light.

Solar cells will play an important role in future energy production. Thin-layer solar modules in particular have advantages as regards low consumption of materials and facilitated mass production. Solar modules of this type are constructed from amorphous or polycrystalline semiconductor materials which can be inexpensively deposited on substrates, in particular glass substrates, with large surface areas. The most important examples are solar modules based on cadmium sulphide-cadmium telluride (CdS/CdTe), copper-indium-diselenide (CIS—GIGS) or amorphous silicon (a—Si).

Thin-layer solar modules consist of a plurality of layers which are deposited in succession on the substrate and which may be processed further.

Thin-layer solar modules with what is known as a “superstrate” configuration start, from the substrate (usually glass), with deposits of the transparent front contact layer, the opaque or only slightly transparent, photovoltaically active semiconductor layers and the back contact layer. In the vast majority of prior art solar cells, the back contact layer is not transparent. However, constructions with transparent back contact layers are known.

Thin-layer solar modules with what is known as the “substrate” configuration start, from the substrate, with deposits of the generally opaque back contact layer, the opaque, photovoltaically active semiconductor layers and the transparent front contact layer. As a rule, the front contact layer is produced from transparent conductive oxides (TOO), for example tin-doped indium oxide (ITO), fluorine-doped tin oxide (FTO) or aluminium-doped zinc oxide (AZO) as well as stannate compounds, for example cadmium stannate (Cd₂(SnO₄)).

The photovoltaic transformation of solar energy into electrical energy typically produces voltages of less than 1 volt in prior art solar cells. In order to obtain voltages which are of practical application, then, a plurality of individual solar cells have to be connected in series.

With thin-layer solar modules, this is preferably accomplished by dividing the active surface of the solar module into individual, strip-shaped solar cells. This division is carried out using what are known as structuring strips, wherein each structuring strip preferably consists of three closely adjacent structuring lines. In a preferred embodiment, each part-line severs only specific individual layers of the sequence of layers in the solar module. By appropriate arrangement of the part-lines with respect to each other and, if necessary, by filling in the structuring lines with conductive or insulating material, the back contact of one solar cell can be brought into contact with the front contact layer of the next solar cell and the front and back contacts are respectively severed in front of or behind the contact site, thereby producing the in-series connection of this solar cell. This procedure is also known as structuring. Correspondingly, a thin-layer solar module of the prior art comprises a plurality of individual solar cells which preferably extend from one edge to the other edge of the solar module (or up to the edges of the solar module which have been stripped of coating). The individual strip-shaped solar cells are separated from each other by the structuring strips and connected in series with each other. Various methods for structuring are known in the prior art; in these methods, as a rule, the coatings are completely or partially removed in the region of the structuring strips in the form of individual structuring lines. This is carried out, for example, by mechanical procedures, laser processing procedures, paste scribing methods or lift-off techniques (see DE 37 12 589 A1 and DE 43 24 318 C1). The structuring strips preferably extend parallel to one another.

An essential aspect of photovoltaic energy production is the surface area required to deploy the solar modules. From an economic and ecological standpoint in particular, the solar modules should if possible be mounted on roofs; increasingly, though, integrating the solar modules into the facades of buildings, in particular high-rise building facades, is becoming more popular.

For use in high-rise building facades, solar modules are constructed in a manner such that they can function as a typical facade cladding. In addition, they advantageously produce electrical energy which can be used in the building or be fed into the public electricity supply.

Building facades, in particular high-rise building facades, generally have to fulfil specific architectural requirements. In particular, regions of the facade cladding have to be made partially transparent. Even when the region of the facade does not contain any windows, but is only in front of a functional space that does not require any direct incident light, a certain ingress of light might nevertheless be desirable.

In this case, partially transparent facade elements may be advantageous.

Conventional thin-layer solar modules from the prior art have no or much too little partial transparency. Even thin-layer solar modules with their special structuring pattern to connect the individual solar cell strips in series do not exhibit much transparency, because the total width of the transparent structural sections is much less than 0.1 mm and the structuring regions are typically more than 5 mm apart. As a rule, then, prior art thin-layer solar modules are substantially less than 2% transparent to incident light.

Thus, the object of the invention is to provide thin-layer solar modules which, in addition to energy production, allow light to gain ingress into the region facing away from the incident light side. In particular, the visual impression should be as close as possible to that of a closed, regular and homogeneous surface, since solar modules also often have to satisfy aesthetic requirements when being used as facade elements.

The object is accomplished by the invention as claimed in claim 1. Advantageous embodiments are disclosed in the claims which are dependent on claim 1. An embodiment in accordance with the invention is described in claim 8. Advantageous embodiments are disclosed in the dependent claims.

In accordance with the invention, the object is accomplished by producing a partial transparency in the solar module, wherein freely definable surface regions (transparent surface regions) of the stack of layers of the thin-layer solar cell of a module of this type, preferably prior to lamination, are selectively removed from a thin-layer solar module using a suitable process, or wherein the stack of layers is exclusively produced on the substrate outside freely definable surface regions (transparent surface regions). The freely definable surface regions are preferably configured in a manner such that the free regions penetrate through at least all of the opaque layers, so that a type of window is formed in the stack of layers of the solar cell through which light can pass.

The solar module of the invention has a plurality of freely definable surface regions which do not contain a stack of layers, or indeed only contain translucent layers of the stack of layers. The fraction of the freely definable surface regions is preferably between 70% and 5%, particularly preferably between 50% and 10% and more particularly preferably between 40% and 20% of the total area of the solar module. A particularly advantageous surface fraction has been shown to be that of 30%±5%.

In a preferred embodiment, the configuration of the freely definable surface regions is such that at each site provided for a surface region, all of the layers of the stack of layers, but at the very least the opaque layers of the stack of layers, are removed.

Subsequent removal of the stack of layers of the thin-layer solar module in the defined surface regions is preferably carried out using a laser process, similar to that used when structuring the thin-layer module. The mechanical processes mentioned above, which involve gravure and sandblasting effects or special lift-off mechanisms as well as suitable photolithographic processes, are also preferred.

In a further preferred embodiment, the freely definable surface regions are constructed by limiting the deposition of all of the layers of the stack of layers, but at least the opaque layers, to the regions outside the freely definable surface regions. Technical procedures from the prior art, such as masking, are suitable in this instance. In this procedure, the layers are deposited in a manner such that defined surface regions (the freely definable surface regions) remain uncoated and the partial transparency is produced in this manner.

In principle, the freely definable surface regions may have any shape. Preferably, however, simple geometrical shapes such as rectangles, trapeziums, triangles, polygons or circles are used. The shapes are selected in a manner such that they can be disposed in as symmetrical a manner as possible along a solar cell strip provided by structuring. The broader the solar cell strips, the greater is the variety of possible shapes. Preferably, the fraction of the freely definable surface regions is the same in each solar cell strip of a solar cell module.

In a preferred embodiment, the transparency is produced by making the structuring lines wider.

In a preferred embodiment, the freely definable surface regions are filled in with a colourless or coloured transparent plastic so that a flat surface is formed which closes off the back contact layer. By using a coloured plastic, advantageous aesthetic embodiments of the solar cell module can be obtained. This filling of the freely definable surface regions is preferably carried out by means of a photolithographic process which is known in the art. An example of the plastic material which may be used is PMMA.

By removing the photovoltaically active layers in the defined surface regions, in the ideal case the efficiency of the thin-layer solar module is only reduced in the ratio of the removed regions to the total photovoltaically active surface. In these cases, the shapes of the surfaces are preferably selected in a manner such that the photovoltaic surfaces obtained between the removed surfaces are rectangular in shape. This ensures that the residual photovoltaically active surfaces obtained between two adjacent structuring lines have the same width b and are rectangular in shape. Thus, for the photovoltaic current generated along the rectangular residual photovoltaic surfaces in the rectangular surface regions Δx*b (Δx=length) as in the original solar cell strips, a current path is provided with a constant width b for the rectangle s. If all of the rectangular photovoltaically active residual surfaces have a width b between the structuring lines, then the electrical conditions as regards the series resistance and current density satisfy the original thin layer solar module's circuit principle. Only the delivered total current, and thus the efficiency, is reduced in the ratio of the removed surface regions to the total photovoltaically active surface area.

Photovoltaically ideal transparent surface regions are thus rectangles which extend over the entire solar cell strip and are disposed in a manner such that the photovoltaically active residual surface per solar cell strip is the same for all solar cell strips of the thin-layer solar module.

The dimensions of the freely definable surface regions are selected as a function of the envisaged field of application of the solar cell module. When the surface equipped with the solar cell modules has to appear smooth and homogeneous, then the freely definable surface regions are very small so that from a certain distance, an observer can no longer make them out individually. In a further preferred embodiment, the freely definable surface regions form isolated design elements of the surface to be provided with solar cell modules. Here, the dimensions are so large that the surface regions are visible to the observer.

In order to comply with other aesthetic and architectural requirements, however, more complex patterns are required. Thus, in a further preferred embodiment, the photovoltaically active residual surfaces may be in the form of a parallelogram with the width of the parallelogram being b and the structuring lines, rather than meeting at the width b of the parallelogram, are laterally offset by any distance. Circular and elliptical shapes are also preferred shapes for the transparent, photovoltaically inactive surface regions. However, trapezoidal and triangular shapes may also result in photovoltaically active remaining regions of different widths, depending on the arrangement. Under such conditions, considerable additional series resistance effects are generated because the current paths become longer than in the original thin-layer module and the constrictions to the current path when varying the width of the photovoltaically active residual surface can result in locally higher current densities. In individual cases, the current densities which might be obtained should be investigated or simulated as to whether they are acceptable or, for example, should be compensated for by increasing the thickness of the material (layer thickness).

In order to avoid the compromising series resistance effects described above to a large extent, in a particularly preferred procedure, the process is configured in a manner such that when removing the stack of layers of the thin-layer solar module, the conductive transparent front contact layer remains intact. In this manner, the photovoltaic current produced in the photovoltaically active residual surfaces in the region of the front contact layer will retain the original current paths of the thin-layer solar module in their entirety, avoiding negative series resistance effects because the current path will not in any way be made longer or, alternatively, unwanted local increases in the current density of the photovoltaically generated current will not occur.

The advantageous effect described is of particular significance with the front contact layer because the surface resistance R_{square, front} of the front contact layer is usually up to a factor of 10 higher than the surface resistance of the back contact R_{square, back} which thus also only has to remain in the region of the photovoltaically active residual surface. On the other hand, the thickness of the back contact layer can also easily be increased in case series resistance effects occur. In contrast, the thickness of the front contact layer is optimized to photovoltaic efficiency (transmission of incident light) and could only be made thicker at the expense of a further loss of efficiency.

The invention will now be explained in more detail with the aid of several exemplary embodiments.

The accompanying figures serve to explain the exemplary embodiments:

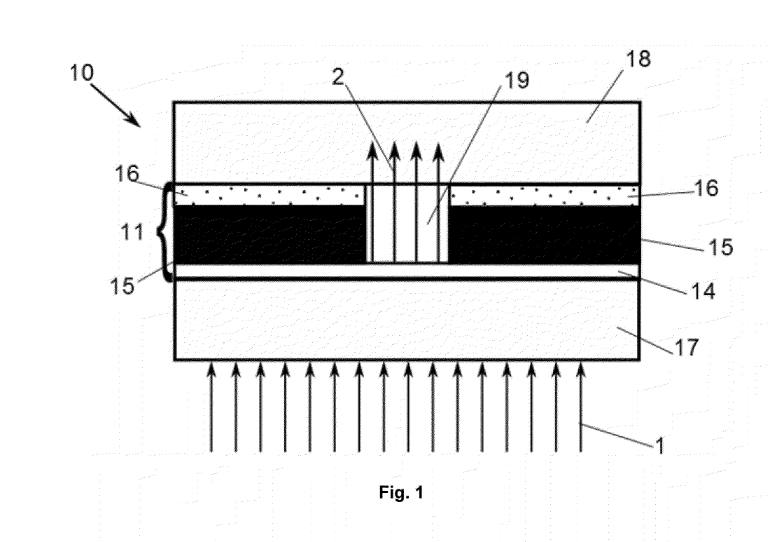

FIG. 1 diagrammatically shows the inventive principle for producing the partial transparency in a thin-layer solar module 10 in cross section. The solar cell 11 consists of the stack of layers comprising the following layers:
transparent front contact 14,
opaque CdS/CdTe layer 15, and
opaque back contact layer 16.

The solar cell is deposited on the front glass 17. The desired partial transparency is obtained by removing defined transparent regions 19 of the opaque layers 15 and 16. The process of removing the defined, opaque layers 15 and 16 in this “superstate” configuration of the thin-layer solar module 10 is carried out in a manner such that the transparent front contact layer 14 remains intact (avoiding additional series resistance). Next, the back glass 18 is laminated on in the normal manner in the manufacture of the thin-layer solar module 10.

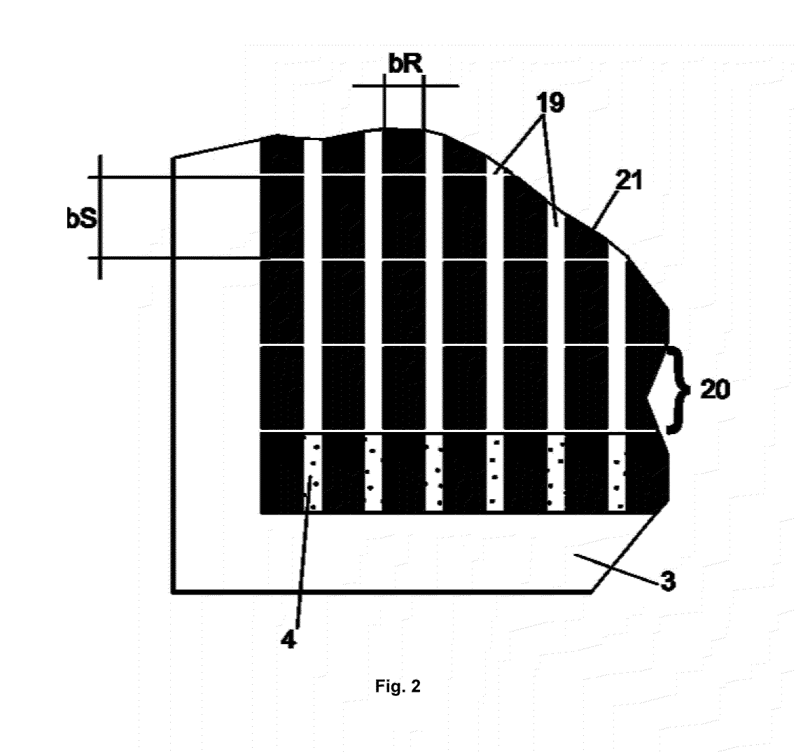

FIG. 2 diagrammatically shows a section of a thin-layer solar module 10 in which rectangles have been removed from the surfaces of the opaque layers 15 and 16 of the solar cell strips 20 in a manner such that photovoltaically active residual surfaces 21 with width b_{rectangle} remain, the length bₛₜᵣᵢₚ of which extends over the entire solar cell strips 20. The photovoltaic residual surfaces 21 meet in the region of the solar cell strips 20 adjacent to the structuring lines over the width b_{rectangle}.

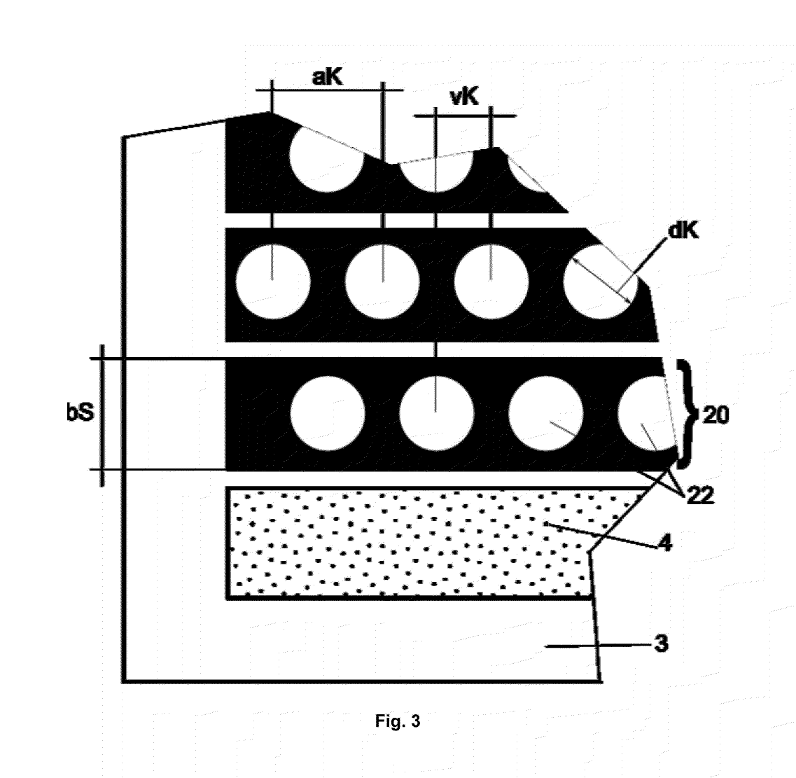

FIG. 3: circles 22 have been removed from the opaque areas 21 of the solar cell strips 20 of the thin-layer solar module 10 at a fixed separation a_{circle} and with a defined diameter d_{circle} along the central line of the solar cell strip 20, wherein: d_{circle}<bₛₜᵣᵢₚ. The central points of the circles 22 of adjacent solar cell strips 20 are each offset by a_{offset}, half the distance of the central point separation a_{circle} between two circles 22 of a solar cell strip 20.

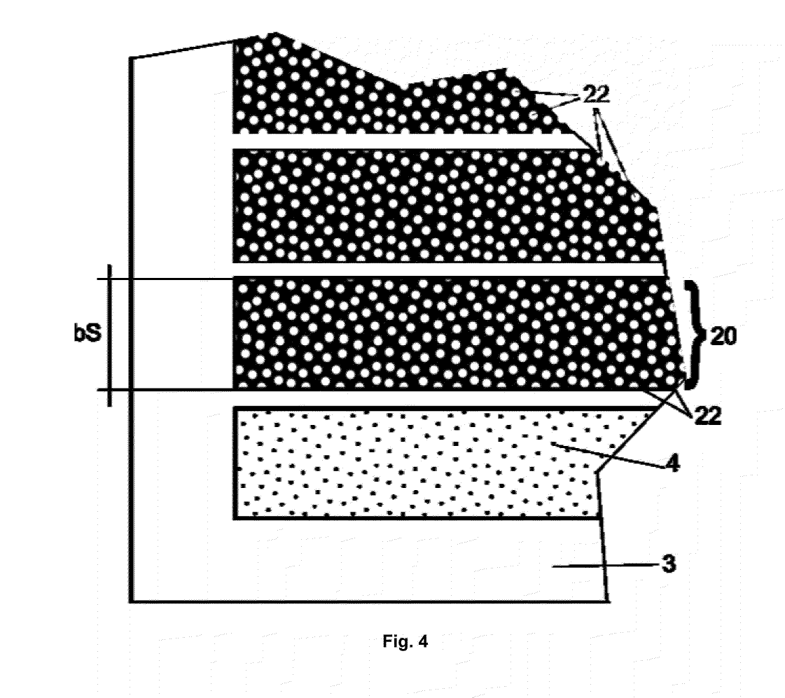

FIG. 4 diagrammatically shows an embodiment with a plurality of circular transparent surface regions 22 which are distributed randomly in the solar cell strips 20. In this embodiment, the dimensions of the circular transparent surface regions 22 are much smaller than the width bₛₜᵣᵢₚ of the solar cell strips.

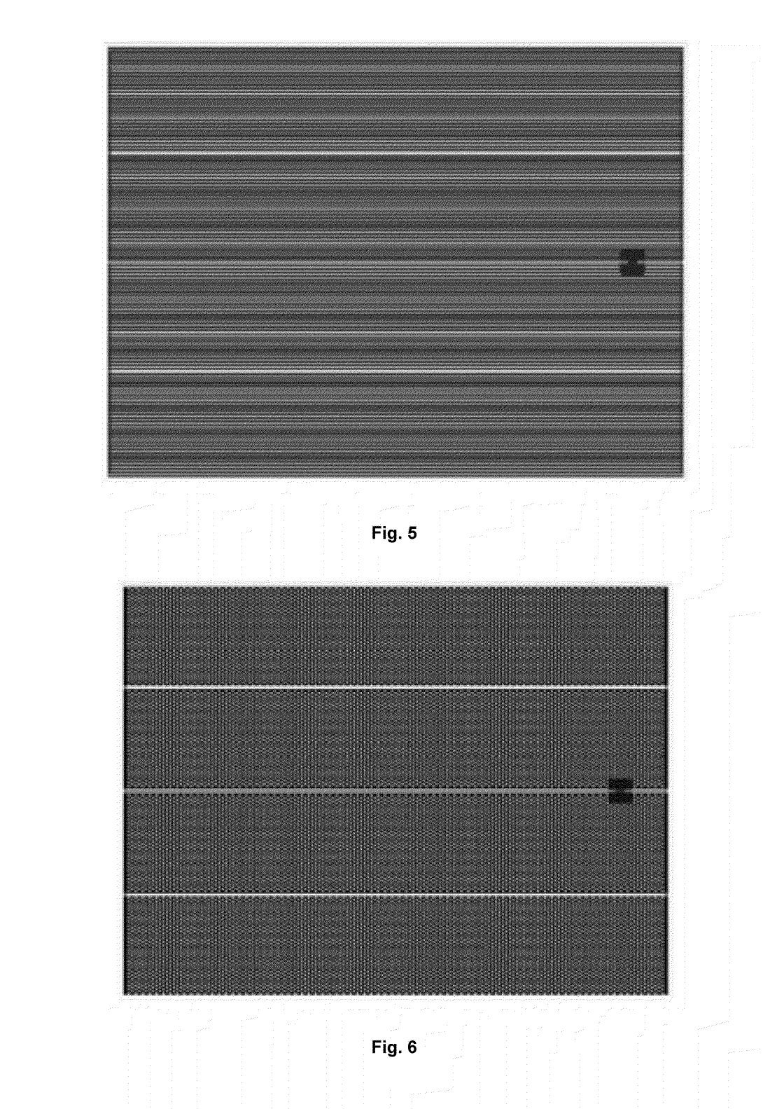

FIG. 5 shows the production of a “rectangular transparency” of approximately 30% based on the thin-layer solar module 10 of German registered design DM 073 637.

FIG. 6 shows the production of a “circular transparency” of approximately 30% based on the thin-layer solar module of German registered design DM 073 637. This embodiment differs from that shown in FIG. 4 by a regular arrangement of the circular transparent surface regions in the solar cell strips.

### List of Reference Numerals

1 incident light
2 light penetrating through the freely definable surface regions
3 stripped edge of the solar cell module
4 solar cell strips with contact bus
10 thin-layer solar cell module
11 solar cell
14 front contact layer
15 opaque CdS/CdTe layer
16 opaque back contact layer
17 front glass
18 back glass
19 transparent region with removed layer structure (surface region)
20 solar cell strips
21 opaque areas (photovoltaically active regions)
22 circular surface regions (circles)
bR width b_{rectangle} of rectangular active residual surfaces
bS length bₛₜᵣᵢₚ of rectangular active residual surfaces
aK separation a_{circle} of circular surface regions (circles)
dK diameter d_{circle} of circular surface regions (circles)
vK separation a_{offset} of the central points of the circular surface regions (circles) in adjacent strips

1. A partially transparent thin-layer solar module with a transparent substrate onto which a coating has been applied, wherein the coating comprises at least one transparent front contact layer, a photovoltaically active semiconductor layer which is opaque or only slightly transparent and a transparent or opaque back contact layer, and the coating is divided into individual strips of solar cells which are connected in series by means of structuring strips, wherein at least the semiconductor layer and back contact layer comprise defined surface regions which lack the material of these layers.

2. The partially transparent thin-layer solar module as claimed in claim 1, wherein the front contact layer is intact within the defined surface regions.

3. The partially transparent thin-layer solar module as claimed in claim 1, wherein the transparent surface regions are disposed on the module surface in a random or regular manner.

4. The partially transparent thin-layer solar module as claimed in claim 1, wherein preferably, the transparent surface regions:
are disposed symmetrically along the solar cell strips,
do not exceed the width of the solar cell strip,
have the same total area of the transparent surface regions for all of the solar cell strips.

5. The partially transparent thin-layer solar module as claimed in claim 1, wherein the defined surface regions are coated with a transparent or coloured transparent plastic.

6. The partially transparent thin-layer solar module as claimed in claim 1, wherein the defined surface regions with the removed semiconductor layer and back contact layer are produced by widening the structuring lines to any extent to produce the desired partial transparency.

7. The partially transparent thin-layer solar module as claimed in claim 1, wherein the defined surface regions with the removed semiconductor layer and back contact layer are in the region of the solar cell strips and have the following shape:
rectangular
parallelogram
circular
triangular
trapezoidal
polygonal.

8. A method for the manufacture of a partially transparent thin-layer solar module as claimed in claim 1, wherein the defined surface regions in the semiconductor layer and back contact layer are removed by means of a:
laser process,
mechanical scoring process,
lift-off process,
etching process,
sandblasting process.

9. The method for the manufacture of a partially transparent thin-layer solar module as claimed in claim 1, wherein the defined surface regions in the semiconductor layer and back contact layer remain uncoated when depositing these layers by being masked.

10. A method for the manufacture of a partially transparent thin-layer solar module in a substrate configuration, comprising at least the following steps:
providing a substrate
applying a transparent or opaque back contact layer
applying a photovoltaically active semiconductor layer which is opaque or only very slightly transparent
applying a transparent front contact layer
structuring the layers by means of parallel structuring strips and dividing the coating into individual solar cell strips which are connected in series,
wherein
defined surface regions are removed from the back contact layer and the semiconductor layer prior to depositing the front contact layer
the removed surface regions are filled in with a transparent or coloured transparent plastic and then the transparent front contact layer is deposited over the transparent and opaque surface regions.

11. A method for the manufacture of a partially transparent thin-layer solar module in a superstrate configuration, comprising at least the following steps:
providing a substrate
applying a transparent or opaque front contact layer
applying a photovoltaically active semiconductor layer which is opaque or only very slightly transparent
applying a transparent or opaque back contact layer
structuring the layers by means of parallel structuring strips and dividing the coating into individual solar cell strips which are connected in series,
wherein
defined surface regions are removed from the back contact layer and the semiconductor layer.

12. The method for the manufacture of a partially transparent thin-layer solar module in a superstrate configuration as claimed in claim 11, wherein the removed surface regions are coated with a transparent or coloured transparent plastic.

13. The partially transparent thin-layer solar module as claimed in claim 2, wherein the transparent surface regions are disposed on the module surface in a random or regular manner.

14. The partially transparent thin-layer solar module as claimed in claim 2, wherein preferably, the transparent surface regions:
are disposed symmetrically along the solar cell strips,
do not exceed the width of the solar cell strip,
have the same total area of the transparent surface regions for all of the solar cell strips.

15. The partially transparent thin-layer solar module as claimed in claim 3, wherein preferably, the transparent surface regions:
are disposed symmetrically along the solar cell strips,
do not exceed the width of the solar cell strip,
have the same total area of the transparent surface regions for all of the solar cell strips.

16. The partially transparent thin-layer solar module as claimed in claim 2, wherein the defined surface regions are coated with a transparent or coloured transparent plastic.

17. The partially transparent thin-layer solar module as claimed in claim 3, wherein the defined surface regions are coated with a transparent or coloured transparent plastic.

18. The partially transparent thin-layer solar module as claimed in claim 4, wherein the defined surface regions are coated with a transparent or coloured transparent plastic.

19. The partially transparent thin-layer solar module as claimed in claim 2, wherein the defined surface regions with the removed semiconductor layer and back contact layer are produced by widening the structuring lines to any extent to produce the desired partial transparency.

20. The partially transparent thin-layer solar module as claimed in claim 3, wherein the defined surface regions with the removed semiconductor layer and back contact layer are produced by widening the structuring lines to any extent to produce the desired partial transparency.
